(19) United States
(12) Patent Application Publication
(10) Pub. No.: US 2026/0164620 A1
(43) Pub. Date: Jun. 11, 2026

(54) MEMORY DEVICE AND COMPUTING SYSTEM

(71) Applicant: SK hynix Inc., Icheon-si (KR)

(72) Inventors: Nam Hyeon CHOI, Icheon-si (KR); Jun Heum BAE, Icheon-si (KR); Seung Yeob BAEK, Icheon-si (KR); Taek Moo LEE, Icheon-si (KR); Jeong Bae JEON, Icheon-si (KR)

(21) Appl. No.: 19/228,529

(22) Filed: Jun. 4, 2025

(30) Foreign Application Priority Data
Dec. 10, 2024 (KR) 10-2024-0182345

(51) Int. Cl. H05K 7/20

(52) U.S. Cl. CPC H05K 7/20836; H05K 7/20809

(57) ABSTRACT

A computing system includes a processor, a slot board on which the processor is disposed, the slot board including a plurality of slots, and a memory device connected to a corresponding one of the plurality of slots. The memory device includes a board, at least one memory on the board, and a pump assembly being disposed on the board sucking at least a portion of a fluid flowing in a first direction over the processor, and discharging the sucked fluid in a second direction that intersects the first direction.

### CROSS-REFERENCE TO RELATED APPLICATION

The present application claims priority under 35 U.S.C. § 119(a) to Korean Patent Application No. 10-2024-0182345 filed in the Korean Intellectual Property Office on Dec. 10, 2024, which is incorporated herein by reference in its entirety.

### BACKGROUND

### 1. Technical Field

Embodiments of the present disclosure relate to a memory device and a computing system.

### 2. Related Art

A computing system may include a processor which performs data processing or computation and a memory which stores data used for data processing or computation.

The processor included in the computing system, depending on the type thereof, may perform complex computation or perform simple computation in parallel. The memory included in the computing system may be various types of memory such as volatile memory or nonvolatile memory, and may transmit and receive data to and from the processor through various interfaces.

Heat generation of the processor may occur according to the operation of the computing system, and due to the heat generation, the operational performance of the processor may deteriorate.

### SUMMARY

The tasks of embodiments of the present disclosure are not limited to the tasks described in the present disclosure, and other tasks can be understood by those skilled in the art in light of the description of the present disclosure.

Embodiments of the present disclosure are directed to providing measures capable of effectively increasing removal of heat generated from a processor according to the operation of a computing system that includes a processor and a memory and improving the performance of data processing by the processor.

In an embodiment, a computing system may include: a processor; a slot board on which the processor is disposed, the slot board including a plurality of slots; and a memory device connected to a corresponding one of the plurality of slots, the memory device including a board; at least one memory on the board; and a pump assembly bieng disposed on the board, sucking at least a portion of a fluid flowing in a first direction over the processor, and discharging the sucked fluid in a second direction that intersects the first direction.

In an embodiment, a computing system may include: a processor; and a first memory device connected to a first slot, the first memory device including a first board; at least one first memory on the first board; and a pump assembly being disposed on the first board, sucking a fluid flowing over the processor in a first direction, and discharging the sucked fluid in a second direction that intersects the first direction.

In an embodiment, a memory device may include: a board; at least one memory on the board; and a pump assembly disposed on the board, sucking at least a portion of a fluid flowing in a first direction, and discharging the sucked fluid in a second direction that intersects the first direction.

According to the embodiments of the present disclosure, it is possible to provide a memory device in which a cooling method and a cooling function capable of effectively increasing removal of heat generated from a processor according to the operation of a computing system while minimizing additional power consumption are implemented.

Effects of the embodiments of the present disclosure are not limited to those described in the present disclosure and other effects can be understood by those skilled in the art in light of the description of the present disclosure.

### BRIEF DESCRIPTION OF THE DRAWINGS

Embodiments of the present disclosure will be more fully understood from the detailed description to be made below and the accompanying drawings, which are provided for illustration only and are not intended to limit various embodiments of the present disclosure.

FIGS. 1A and 1B are views illustrating an example of a cooling method of a computing system according to embodiments of the present disclosure.

FIGS. 2A and 2B are views illustrating an example of a cooling method of a computing system according to embodiments of the present disclosure.

FIG. 3 and FIG. 4 are views illustrating examples of the structure of a cooling assembly included in a computing system according to embodiments of the present disclosure.

FIGS. 5, 6, and FIG. 7 are views illustrating examples of the disposition structure and operation method of a cooling assembly of a computing system according to embodiments of the present disclosure.

FIGS. 8, 9, and 10 are charts illustrating examples of the process of a method for operating a cooling assembly of a computing system according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein may be omitted for the interest of brevity. The terms such as “including,” “having,” “containing,” “constituting,” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements etc., but is used merely to distinguish the corresponding element from other elements.

Throughout the specification and claims, a first element “on” a second element indicates that the first element can be “directly on” the second element, or that at least one intervening element can be interposed between the first and second elements. When a first element “is connected or coupled to,” “contacts or overlaps,” etc. a second element, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element may be included in at least one of two or more elements that “are connected or coupled to,” “contact or overlap,” etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” encompasses the meanings of the term “can.”

Hereinafter, some embodiments of the present disclosure will be described in detail with reference to accompanying drawings.

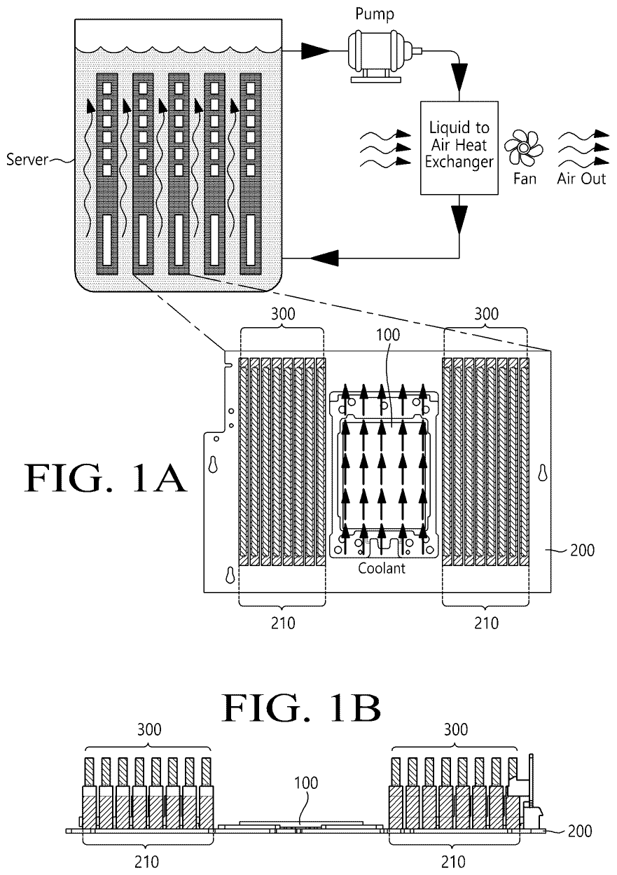

FIG. 1 is a view illustrating an example of a cooling method of a computing system according to embodiments of the present disclosure.

Referring to FIG. 1, as an example of a computing system, a server including a processor 100 and a memory device 300 is illustrated. The computing system may include at least one processor 100. The processor 100 may be one of various processing devices which perform data processing or computation. The processor 100 may be one of processing devices such as, for example, a central processing unit (CPU), a graphics processing unit (GPU), a neural network processing unit (NPU), and a tensor processing unit (TPU), but is not limited thereto.

The computing system may include at least one memory device 300 which stores data used when performing data processing or computation by the processor 100. The memory device 300 may be volatile memory such as DRAM, but is not limited thereto. The computing system may include nonvolatile memory such as NAND flash, or may include volatile memory and nonvolatile memory.

The memory device 300 may be connected to a slot 210 which is disposed on a slot board 200. The slot board 200 may also be referred to as a motherboard. The processor 100 may be disposed on the slot board 200. In some embodiments, a board on which the processor 100 is disposed may be separated from the slot board 200. A plurality of slots 210 may be disposed on the slot board 200. Memory devices 300 may be disposed in at least some of the plurality of slots 210.

The processor 100 may transmit and receive data to and from the memory device 300 and perform processing or computation using data.

According to the operation of the computing system, the temperature of a component such as the processor 100 or the memory device 300 may increase. In particular, heat generation may occur due to the operation of the processor 100. Due to increase in the temperature of the computing system, the operational performance of the computing system may degrade.

The computing system may adjust the increasing temperature by controlling the operation of the processor 100. Alternatively, the computing system may include a cooling module (or a cooling assembly), and by using the cooling module, may lower the temperature of a component such as the processor 100 or the memory device 300.

For example, by flowing a coolant toward the processor 100, or the memory device 300, or both, a temperature of the processor 100, or a temperature of the memory device 300, or both may be lowered. FIG. 1A illustrates an example of a server viewed from the front, and FIG. 1B illustrates an example of the server viewed from the bottom.

The coolant may flow, for example, from the bottom to the top of the server. The coolant may flow over the upper surface of the processor 100 while flowing from the bottom to the top of the server. The coolant may flow over a surface (e.g., the side surface) of the memory device 300 connected to the slot 210. The coolant may lower the temperature of the processor 100 while flowing over the upper surface of the processor 100.

The coolant may flow through a pump included inside or near the computing system, and according to the flow of the coolant, the temperature of a component such as the processor 100 or the memory device 300 may be lowered. It is possible to prevent or reduce the degradation of operation performance due to temperature increase that occurs according to the operation of the computing system.

In addition, the computing system according to the embodiments of the present disclosure may further improve the cooling performance of the computing system by using a device which is disposed near the processor 100 or the memory device 300 and assists a cooling function.

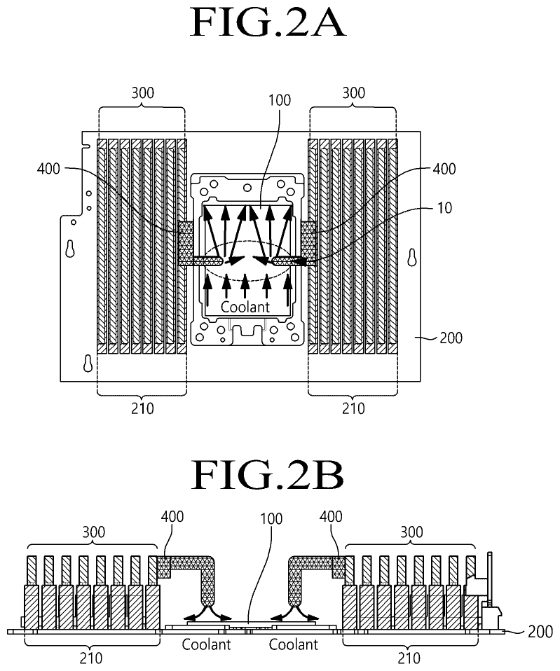

FIG. 2 is a view illustrating an example of a cooling method of a computing system according to embodiments of the present disclosure.

Referring to FIG. 2, the computing system may include at least one processor 100 and at least one memory device 300. FIG. 2A illustrates an example of the front view of the processor 100 and the memory device 300 included in the computing system, and FIG. 2B illustrates an example of the bottom view of the processor 100 and the memory device 300.

The processor 100 may be disposed on a slot board 200. As the case may be, the processor 100 may be disposed on a board which is separated from the slot board 200. The slot board 200 may include a plurality of slots 210. The plurality of slots 210 may be located near (or adjacent to) the processor 100.

Memory devices 300 may be disposed in at least some of the plurality of slots 210. The memory device 300 may be disposed, for example, in a direction perpendicular to the processor 100 (e.g., an upper surface of the processor 100).

In some embodiments, the memory device 300 may be disposed on a plane that is the same as or parallel to the processor 100 (e.g., an upper surface of the processor 100). Alternatively, a plane on which the processor 100 is disposed and a plane on which the memory device 300 is disposed may intersect each other, and an intersection angle may be 45 degrees or less.

Depending on the disposition pattern of the slots 210 located near the processor 100, the memory device 300 may be disposed in a given direction (e.g., a predetermined direction) with respect to a direction in which the processor 100 is disposed.

At least one of the memory devices 300 may include a pump module (or a pump assembly) 400. For example, the pump module 400 may be included in a memory device 300 which is disposed in a slot 210 located most adjacent to the processor 100 among the plurality of slots 210 included in the slot board 200. The pump module 400 may be implemented integrally with the memory device 300 or may be implemented in a shape which is detachable from the memory device 300.

The pump module 400 may suck a fluid which flows in a first direction over the processor 100, or the memory device 300, or both. The fluid may refer to a coolant.

The pump module 400 may discharge the sucked fluid in a second direction that intersects the first direction. The first direction may indicate, for example, a direction that is parallel to the upper surface of the processor 100. The first direction may indicate a direction in which the coolant flows from bottom to top over the upper surface of the processor 100, or a direction in which the coolant flows from top to bottom over the upper surface of the processor 100. The second direction may indicate, for example, a direction that is perpendicular to the upper surface of the processor 100. Alternatively, the second direction may indicate a direction that is oblique to the upper surface of the processor 100. The second direction may indicate a direction that intersects the first direction in which the coolant flows over the upper surface of the processor 100 and meets the coolant flowing in the first direction.

The pump module 400 may suck the coolant which flows from bottom to top, for example, in the first direction. The pump module 400 may discharge the sucked coolant toward the upper surface of the processor 100 in the second direction.

The pump module 400 may be mounted on a surface (e.g., the side surface) of the memory device 300. The pump module 400 may suck the coolant flowing over the upper surface of the processor 100 and over the side surface of the memory device 300, and then, may discharge the sucked coolant toward the upper surface of the processor 100.

The coolant discharged by the pump module 400 may meet the coolant flowing in the first direction. Since the coolant discharged in the second direction meets the coolant flowing in the first direction, the speed of the coolant may increase in a corresponding area. The speed of the coolant which flows over and proximate to the upper surface of the processor 100 may increase.

Since the coolant is discharged toward the upper surface of the processor 100 in the second direction intersecting the first direction by the pump module 400, the efficiency of cooling the processor 100 may be increased. For example, by increasing the flow speed of the coolant which flows in the first direction on the upper surface of the processor 100 and increasing a pressure that is applied to the upper surface of the processor 100 by the coolant discharged in the second direction, the effect of lowering the temperature of the processor 100 may be improved.

As in the example illustrated in FIGS. 2A and 2B, the pump module 400 may be mounted on the memory device 300 which is connected to a slot 210 most adjacent to the processor 100 among the plurality of slots 210. In some embodiments, the pump module 400 may be mounted on each of at least two memory devices 300 among the memory devices 300 which are connected to the slots 210. For example, a pair of pump modules 400 may be mounted on a pair of memory devices 300 most adjacent to the processor 100, respectively, such that side surfaces of the pair of memory devices 300 on which the pair of the pump modules 400 are mounted are opposite to each other. In order to lower the temperature of the processor 100, or the memory device 300, or both, the pump module 400 may be disposed in a structure capable of discharging the coolant toward one or more corresponding components.

The slots 210 each may be disposed not in a direction perpendicular to the processor 100 but in a direction parallel to the processor 100. Even in this case, the pump module 400 may be mounted on the memory device 300 which is mounted in a slot 210. The pump module 400 may be disposed in a structure capable of sucking the coolant flowing in the first direction and discharging the sucked coolant toward the processor 100 or the memory device 300.

The pump module 400 may be disposed in a partial area of the memory device 300, and may be included in the memory device 300 like other components disposed in the memory device 300.

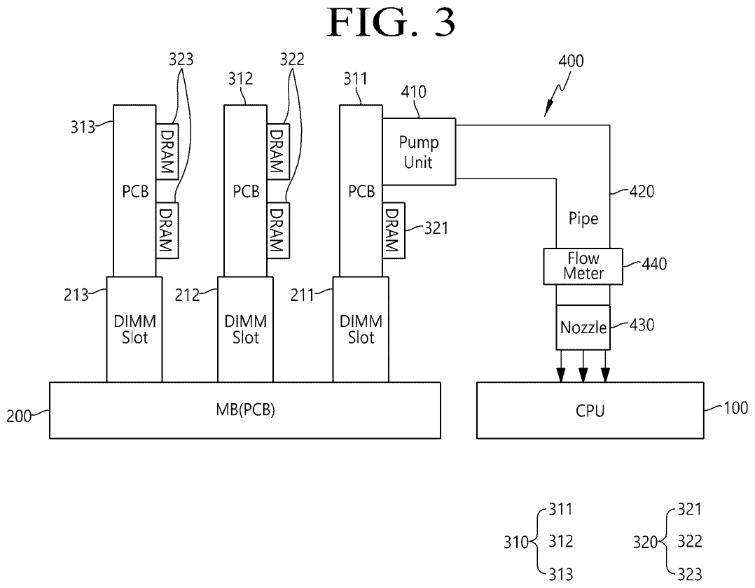

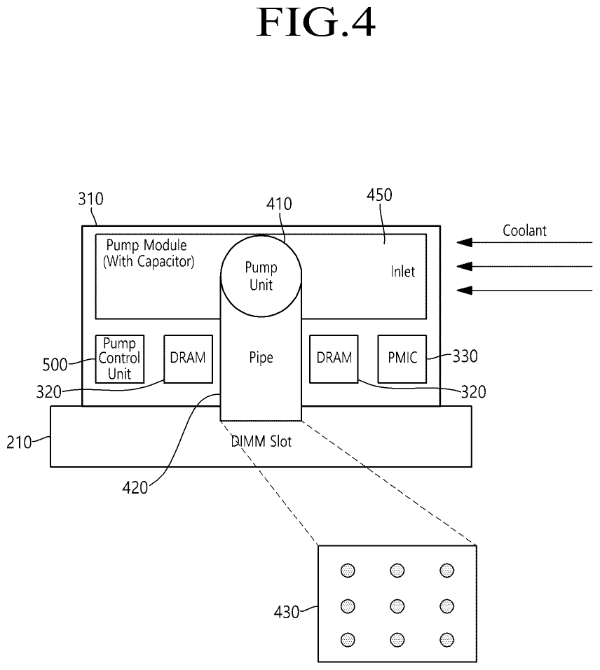

FIG. 3 and FIG. 4 are views illustrating examples of the structure of a cooling module (or a cooling assembly) included in a computing system according to embodiments of the present disclosure.

Referring to FIG. 3 and FIG. 4, a processor 100 may be disposed, and a slot board 200 may be located near the processor 100. As the case may be, the processor 100 may be located on the slot board 200.

A plurality of slots 210 may be located on the slot board 200. Among the plurality of slots 210, a first slot 211, a second slot 212 and a third slot 213 may be disposed in an order in which they are adjacent to the processor 100. The number of slots 210 is an example, and the number of slots 210 located near the processor 100 may vary according to embodiments.

Memory devices 300 may be mounted in at least some of the plurality of slots 210. A memory device 300 may be disposed in each of the first slot 211, the second slot 212, and the third slot 213.

Each memory device 300 may include a board 310 and at least one memory 320 on the board 310. At least one of the memory devices 300 may include a pump module 400 which is disposed on the board 310. For example, the pump module 400 may be mounted on the memory device 300 which is disposed in the first slot 211 most adjacent to the processor 100 among the plurality of slots 210.

The memory device 300 disposed in the second slot 212 and the memory device 300 disposed in the third slot 213 each may not include the pump module 400.

One or more memories 320 (e.g., a first memory 321, second memories 322, or third memories 323 in FIG. 3) which are disposed on the board 310 (e.g., a first board 311, a second board 312, or a third board 313 in FIG. 3) of each memory device 300 may be located on only a single surface of the board 310 or may be located on both surfaces of the board 310. When memories 320 are located on both surfaces of the board 310, the disposition structure of the memories 320 may be different depending on whether the pump module 400 is disposed on the board 310.

For example, a first memory 321 may be disposed on the first surface of a first board 311 of the memory device 300 which is disposed in the first slot 211. The first surface may indicate a surface which faces the processor 100. The pump module 400 may be disposed in an area on the first surface of the first board 311 where the first memory 321 is not disposed.

A first memory 321 may be further disposed on the second surface of the first board 311 which faces away from the first surface of the first board 311. For example, the second surface of the first board 311 is opposite to the first surface of the first board 311. The number of first memories 321 disposed on the second surface of the first board 311 may be different from the number of first memories 321 disposed on the first surface of the first board 311. The number of first memories 321 disposed on the second surface of the first board 311 may be greater than the number of first memories 321 disposed on the first surface of the first board 311.

The structure of the memory device 300 disposed in the second slot 212 or the third slot 213 may be different from the structure of the memory device 300 disposed in the first slot 211.

For example, the memory device 300 disposed in the second slot 212 may include a second board 312 and at least one second memory 322 on the second board 312. The at least one second memory 322 may be disposed on the first surface of the second board 312. Since the pump module 400 is not disposed on the first surface of the second board 312, the number of second memories 322 disposed on the first surface of the second board 312 may be greater than the number of first memories 321 disposed on the first surface of the first board 311.

Second memories 322 may be further disposed on the second surface of the second board 312 which faces away from the first surface. The number of second memories 322 disposed on the second surface of the second board 312 may be the same as the number of second memories 322 disposed on the first surface of the second board 312. The number of second memories 322 disposed on the second surface of the second board 312 may be the same as the number of first memories 321 disposed on the second surface of the first board 311.

Depending on the disposition of the pump module 400, the number and disposition structure of memories 320 disposed in some memory devices 300 may be different from the number and disposition structure of memories 320 disposed in other memory devices 300.

The pump module (or pump assembly) 400 may include, for example, a pump unit (or a pump) 410. The pump unit 410 may control an operation of sucking and discharging a fluid such as a coolant. The pump module 400 may include a pipe 420 which is connected to the pump unit 410. The coolant, which is a fluid, may be discharged through the pipe 420. A nozzle 430 may be disposed at the end of the pipe 420. A flow meter 440 may be disposed on the pipe 420. The pump module 400 may include an inlet 450 through which the coolant is sucked, and the inlet 450 may be disposed, for example, in the first direction in which the coolant flows. The inlet 450 may be disposed in a direction parallel to the upper surface of the processor 100. In some embodiments, the inlet 450 may include one or more slots each extending in the first direction to effectively suck the coolant.

The pump module 400 may be located in an area other than an area where the memory 320 is disposed on the board 310 of the memory device 300. A pump control unit (or a pump control circuit) 500 which controls the operation of the pump module 400 according to an external control signal may be disposed on the board 310. A power management circuit 330 which controls power to be supplied to the memory 320 and the pump module 400 included in the memory device 300 may be disposed on the board 310.

The pump module 400 may be driven by using a portion of power supplied to the memory device 300 connected to the slot 210. For example, power may be allocated to each of the plurality of slots 210 disposed on the slot board 200. Specifically, an amount of power allocated to a first one of the plurality of slots 210 may be substantially the same as that of a second one of the plurality of slots 210. The amount of power used by the memory 320 and so on of the memory device 300 in the power allocated to the slot 210 may be constant. The pump module 400 may operate by using at least a portion of power other than the power used by the memory 320 and so on of the memory device 300 in the power allocated to the slot 210. For example, the power allocated to each of the plurality of slots 210 may include a first portion used to drive the pump module (or pump assembly) 400 and a second portion used by one or more components (e.g., the at least one memory 320) of the memory device 300 other than the pump assembly 400. In some embodiments, the pump assembly 400 is driven using the first portion having power amount equal to or larger than that allocated to the pump assembly 400 during at least a portion of a period in which the at least one memory is 320 driven using the second portion having power amount smaller than that allocated to the at least one memory 320. For example, each of power amount allocated to the pump assembly 400 and power amount allocated to one or more components (e.g., the at least one memory 320) other than the pump assembly 400 of the memory device 300 may be predetermined.

As the case may be, the pump module 400 may include a charging unit (or an energy storage). The charging unit may include, for example, at least one capacitor. The charging unit may accumulate energy with power not used for an operation by the pump module 400 in power that may be used by the pump module 400. As the case may be, the charging unit may accumulate energy with power not used by the memory 320 and so on in the power allocated to the memory 320 and so on. In some embodiments, the pump assembly 400 includes an energy storage which accumulates energy during at least a portion of a period in which the pump assembly 400 is driven using power amount smaller than that allocated to the pump assembly 400.

The pump module 400 may operate using power accumulated by the charging unit. The pump module 400 may operate using the charging unit or using, as the case may be, power equal to or larger than power that may be used by the pump module 400. For example, power amount allocated to the slot 210 may be 30 W, and power amount allocated to the memory 320 and so on of the memory device 300 may be 25 W. In this case, the pump module 400 may operate using 5 W not used in the power amount allocated to the slot 210.

When there is no power amount accumulated in the charging unit of the pump module 400, 5 W may be the maximum of power amount that may be used by the pump module 400. When power is charged to the charging unit, the pump module 400 may operate using power of 5 W or more. An operating stage of the pump module 400 may be adjusted depending on the temperature of the processor 100, and power may be efficiently used through the charging unit.

The pump module 400 may operate according to a control signal received from the outside (e.g., outside of the pump assembly 400), and may discharge the coolant which flows in the first direction and is sucked through the inlet 450, through the pipe 420 in the second direction intersecting the first direction. The pump module 400 may discharge the coolant, for example, toward the upper surface of the processor 100. By discharging the coolant toward the upper surface of the processor 100, the pump module 400 may increase the effect of lowering the temperature of the processor 100.

As the pump module 400 discharges the coolant flowing in the first direction onto the upper surface of the processor 100, a cooling effect by the coolant coming into contact with the processor 100 may be increased. In addition, as the coolant is discharged to the upper surface of the processor 100, the speed of the coolant flowing on the processor 100 may be increased, thereby increasing a cooling effect by the coolant. In addition, by discharge of the coolant to disperse a thermal boundary layer formed on the processor 100, a cooling effect may be increased.

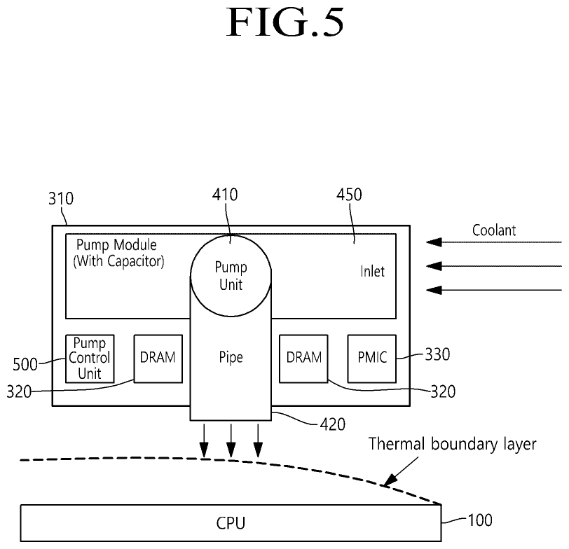

FIG. 5 to FIG. 7 are views illustrating examples of the disposition structure and operation method of a cooling module of a computing system according to embodiments of the present disclosure.

Referring to FIG. 5, an example is illustrated in which a pump module 400 sucks a coolant flowing in a first direction and discharges the coolant in a second direction intersecting the first direction. The first direction may indicate a direction that is parallel to a processor 100. The second direction may indicate a direction that is perpendicular to the processor 100. In some embodiments, the first direction may indicate a direction that is parallel to a surface (e.g., a main surface) of the board 310 on which at least one memory 320 is disposed, and the second direction may be a direction that is perpendicular or oblique to the first direction.

According to the operation of the processor 100, the temperature of the processor 100 may increase. As the temperature of the processor 100 increases, a thermal boundary layer may be formed on the surface of the processor 100. The thermal boundary layer may indicate a layer which is formed by an area exhibiting a relatively high temperature around the processor 100 due to heat generation of the processor 100.

The thermal boundary layer may be formed along the contour of the surface of the processor 100. Alternatively, as in the example illustrated in FIG. 5, the thickness of a thermal boundary layer may increase from an edge where a temperature is relatively low to a central area where a temperature is relatively high. The outer surface of the thermal boundary layer may form a curved shape on the processor 100.

Since a pump module 400 mounted on a memory device 300 discharges the coolant toward the processor 100 on the upper surface of the processor 100, the coolant may be discharged in a direction substantially perpendicular to the surface of the thermal boundary layer.

When the coolant is not discharged by the pump module 400, since the coolant flows in the first direction, the coolant may flow along the outer surface of the thermal boundary layer. In this case, a degree to which the thermal boundary layer is dispersed by the coolant may be relatively low. In contrast, according to embodiments of the present disclosure, the coolant is discharged in the second direction intersecting the first direction by the pump module 400, an effect of dispersing the thermal boundary layer may be increased by the coolant discharged in the second direction.

As the pump module 400 mounted on the memory device 300 discharges the coolant to the upper surface of the processor 100, the thermal boundary layer formed on the surface of the processor 100 may be effectively dispersed. A cooling effect by the coolant flowing near the processor 100 may be improved.

In addition, as the case may be, the effect of cooling the processor 100 may be further increased by adjusting a direction in which the coolant is discharged.

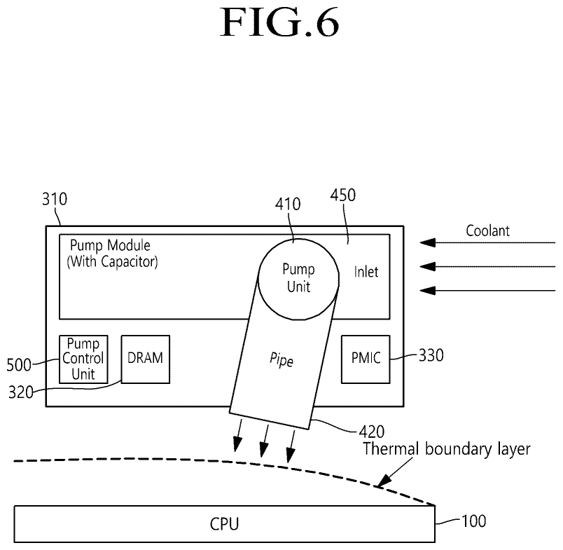

For example, referring to FIG. 6, a memory device 300 may be mounted in a slot 210 which is located adjacent to a processor 100. The memory device 300 may include at least one memory 320 and a pump module 400.

The pump module 400 may suck a coolant flowing in a first direction and discharge the coolant in a second direction. The second direction may be a direction intersecting the first direction, and may be a direction oblique to the first direction.

A pipe 420 of the pump module 400 may be fixedly coupled to the pump unit (or pump) 410 in a specific direction (e.g., an oblique direction). Alternatively, the pipe 420 of the pump module 400 may be rotatably coupled to the pump 410. The pipe 420 of the pump module 400 may be disposed obliquely with respect to the upper surface of the processor 100. For example, an axis of the pipe 420 may be oblique to the upper surface of the processor 100.

The pipe 420 of the pump module 400 may discharge the coolant in a direction that is oblique with respect to the upper surface of the processor 100. A thermal boundary layer may be formed on the upper surface of the processor 100, and the outer surface of the thermal boundary layer may not be flat but may have a curved shape. The thermal boundary layer may have a shape in which the thickness of the thermal boundary layer gradually increases from an area where the temperature of the processor 100 is relatively low to an area where the temperature of the processor 100 is relatively high.

Since the outer surface of the thermal boundary layer has a curved shape, the pipe 420 may be disposed obliquely toward the upper surface of the processor 100 so that the coolant may be discharged in a direction substantially perpendicular to the curve. Since the pipe 420 of the pump module 400 is located obliquely toward the upper surface of the processor 100, the pipe 420 may be located in a direction substantially perpendicular to the outer surface of the thermal boundary layer formed on the processor 100.

The coolant discharged by the pump module 400 may be discharged in a direction substantially perpendicular to the inclined surface of the thermal boundary layer, and an effect of dispersing the thermal boundary layer may be increased.

The pump module 400 may be disposed in various ways according to a temperature distribution in the processor 100. For example, there may be an area with a relatively high temperature and an area with a relatively low temperature in the processor 100. In this case, the pump module 400 may be located to discharge the coolant onto the area with a high temperature. As the case may be, a plurality of pipes 420 may be disposed, and a period of discharging the coolant and a speed of discharging the coolant may be differently controlled for each pipe 420.

In addition, in consideration of a change in the thermal boundary layer formed depending on the temperature of the processor 100, a direction in which the pump module 400 discharges the coolant may be changed, thereby increasing an effect of dispersing the thermal boundary layer on the processor 100 and an effect of removal of heat generated from the processor 100.

The pump module 400 may discharge the coolant in a direction different from a direction in which the coolant flows, thereby increasing an effect of decreasing the temperature of the processor 100, and may variously adjust a direction in which the coolant is discharged, thereby further increasing the effect of decreasing the temperature of the processor 100.

As the case may be, in order to facilitate temperature control of the processor 100, a separate configuration for heat dissipation may be disposed on the processor 100. Even in this case, cooling performance may be improved by using the pump module 400.

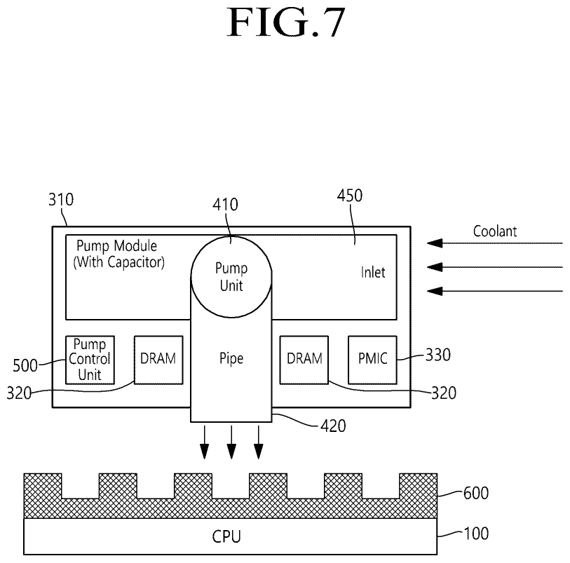

For example, referring to FIG. 7, a heat dissipation member 600 may be disposed on the upper surface of a processor 100. The heat dissipation member 600 may have a material and a structure for dissipating the temperature of the surface of the processor 100 to the outside. For example, the heat dissipation member 600 may include a plurality of grooves which are located on the upper surface of the processor 100.

A memory device 300 having a pump module 400 mounted thereon may be disposed in a slot 210 which is located near the processor 100. The pump module 400 may suck a coolant which flows along the upper surface of the processor 100. The pump module 400 may discharge the sucked coolant toward the upper surface of the processor 100.

As the pump module 400 sucks the coolant flowing in a first direction and discharges the coolant in a second direction intersecting the first direction, the flow speed of the coolant on the surface of the processor 100 may be increased, and cooling efficiency by the coolant may be increased.

When the heat dissipation member 600 including the plurality of grooves is disposed on the processor 100, the pump module 400 may be disposed to discharge the coolant toward a groove of the heat dissipation member 600. A pipe 420 of the pump module 400 may be located to be aligned with the groove of the heat dissipation member 600.

The groove of the heat dissipation member 600 may be an area which is adjacent to the processor 100 compared to the outside of the groove and thus has a relatively high temperature. A thermal boundary layer may be formed inside the groove. The thermal boundary layer may be formed, for example, in an inclined shape which becomes thicker from the center of the groove toward the outside of the groove. As the case may be, the thermal boundary layer may be formed in a convex shape inside the groove.

The thermal boundary layer may be easily formed inside the groove compared to the outside of the groove, and the temperature inside the groove may be higher. Since the pump module 400 which discharges the coolant to the upper surface of the heat dissipation member 600 discharges the coolant toward the groove of the heat dissipation member 600, an effect of dispersing the heat boundary layer may be increased.

Since the pump module 400 which discharges the coolant toward the groove of the heat dissipation member 600 is disposed while providing a heat dissipation effect by disposing the heat dissipation member 600 on the upper surface of the processor 100, an effect of cooling the processor 100 may be improved.

As the case may be, the width of the pipe 420 of the pump module 400 may be larger than the width of the groove of the heat dissipation member 600, and in this case, the pump module 400 may be located to overlap a plurality of grooves. The pump module 400 may be disposed to discharge the coolant toward at least some of the plurality of grooves.

In addition to the example described above, the pump module 400 may be disposed in various structures for facilitating dispersion of a thermal boundary layer which may be formed on the processor 100, and may discharge the coolant toward the processor 100.

The pump module 400 may operate using a portion of power supplied to the slot 210, and the operation level of the pump module 400 may be adjusted depending on available power.

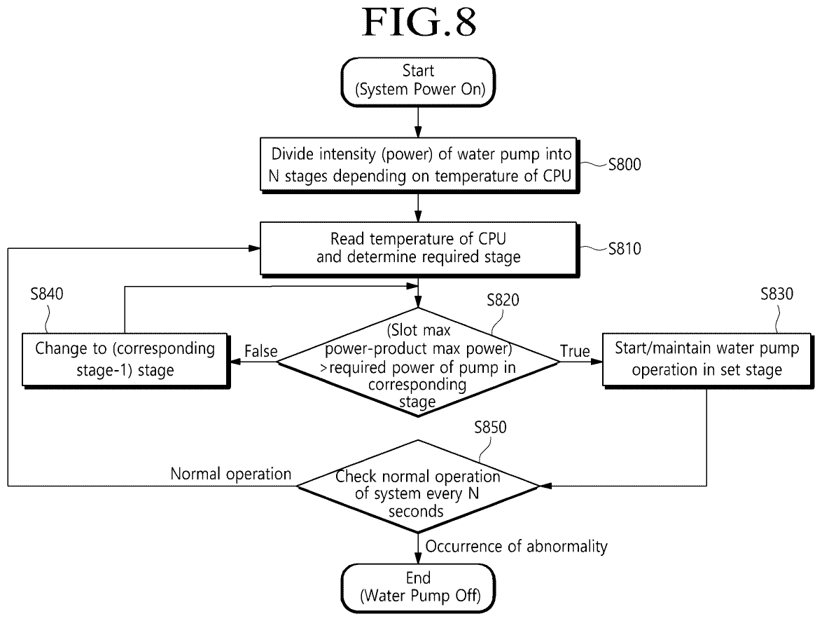

FIG. 8 to FIG. 10 are charts illustrating examples of the process of a method for operating a cooling module of a computing system according to embodiments of the present disclosure.

Referring to FIG. 8, the computing system may be powered on and start to operate. Depending on the temperature of the processor 100 (e.g., a CPU) included in the computing system, the operation intensity of the pump module 400 of the memory device 300 connected to the slot 210 located adjacent to the processor 100 may be divided into N stages (S800).

For example, when the temperature range of the processor 100 is a first temperature range, the pump module 400 may operate in a first stage, and when the temperature range of the processor 100 is a second temperature range higher than the first temperature range, the pump module 400 may operate in a second stage. In the second stage, the operation intensity of the pump module 400 may be greater than the operation intensity of the pump module 400 in the first stage. The operation intensity may indicate, for example, the speed, number of times, range, number of directions, etc. of the coolant discharged by the pump module 400, but is not limited thereto.

The computing system may read the temperature of the processor 100, and thereby, may determine a cooling stage required for the pump module 400 (S810).

The computing system may check whether power for driving the pump module 400 according to the corresponding stage is sufficient.

For example, the computing system may check whether the difference between maximum power allocated to the slot 210 to which the pump module 400 is connected and maximum power used by the memory device 300 is larger than power required by the pump module 400 in the corresponding stage (S820).

When the amount of available power for the pump module 400 is larger than the amount of power required by the pump module 400, since power for driving the pump module 400 is sufficient, the computing system may drive the pump module 400 according to the determined stage (S830).

When the amount of available power is smaller than the amount of power required by the pump module 400, the computing system may lower the operation stage of the pump module 400 by one stage (S840). The computing system may check again whether power for driving the pump module 400 in the lowered operation stage is sufficient, and may drive the pump module 400 according to a determined stage.

The computing system may check the temperature of the processor 100 or the operation state of the pump module 400 at preset intervals after driving the pump module 400 (S850), and may adjust whether to operate the pump module 400 or an operation stage depending on whether the pump module 400 operates normally. Since the computing system drives the pump module 400 using an available portion of power supplied to the slot 210 to which the memory device 300 having the pump module 400 mounted thereon is connected, a cooling function may be provided without using separate power.

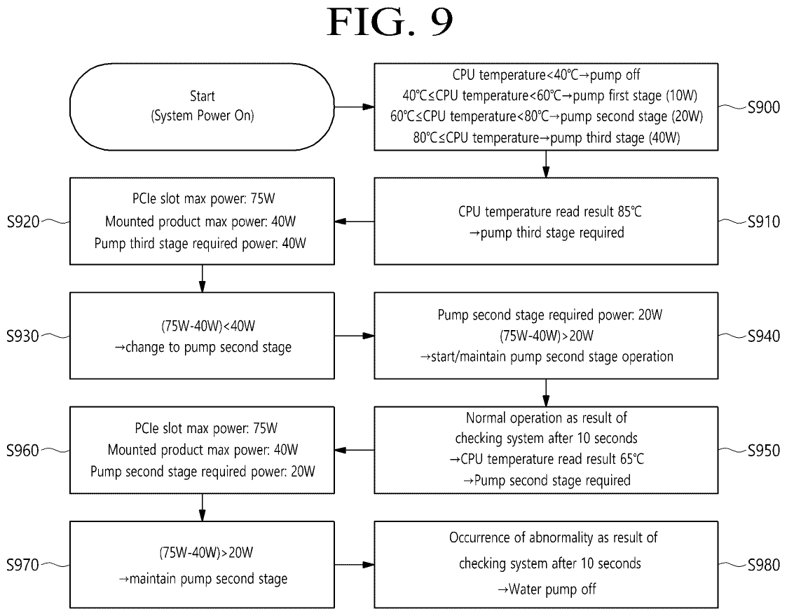

FIG. 9 illustrates a specific example of a method for operating the pump module 400. Referring to FIG. 9, the computing system may be powered on and start to operate.

The operation stage of the pump module 400 may be set depending on the temperature of the CPU which is the processor 100 (S900).

For example, when the temperature of the CPU is lower than 40° C., the pump module 400 may be turned off. When the temperature of the CPU is equal to or higher than 40° C. and lower than 60° C., the operation stage of the pump module 400 may be set to a first stage. In the first stage, the pump module 400 may operate using power amount of 10 W. When the temperature of the CPU is equal to or higher than 60° C. and lower than 80° C., the operation stage of the pump module 400 may be set to a second stage. In the second stage, the pump module 400 may operate using power amount of 20 W. When the temperature of the CPU is equal to or higher than 80° C., the operation stage of the pump module 400 may be set to a third stage. In the third stage, the pump module 400 may operate using power amount of 40 W. The operation stages of the pump module 400 are merely an example. The operation stags of the pump module 400 and power amount required in each operation stage may be vary according to embodiments.

As a result of reading the temperature of the CPU by the computing system, the temperature may be 85° C. In this case, the operation stage of the pump module 400 may require the third stage (S910).

The computing system may check whether power amount required for the corresponding operation stage is sufficient (S920).

For example, maximum power amount according to power allocated to the corresponding slot 210 may be 75 W. Power amount according to power required by the memory 320 and so on mounted on the memory device 300 coupled to the corresponding slot 210 may be 40 W. Power amount required by the pump module 400 for driving the pump module 400 in the third stage may be 40 W.

Because the difference between the power amount allocated to the corresponding slot 210 and the power amount used by one or more components (e.g., the memory 320) other than the pump module 400 is smaller than the power amount required for the operation of the pump module 400, the computing system may change the operation stage of the pump module 400 to the second stage lower than the third stage (S930).

The computing system may check whether power amount according to the changed operation stage is allowed (S940). Because the power amount of 20 W for the operation of the pump module 400 in the second stage is smaller than allowable power amount (35 W=75 W−40 W) for the pump module 400, the computing system may set the operation stage of the pump module 400 to the second stage and drive the pump module 400.

The computing system may check whether the pump module 400 operates normally, at preset intervals (S950). For example, the computing system may check the temperature of the CPU after 10 seconds and the operation stage of the pump module 400 required according to the temperature of the CPU.

When it is checked that the operation of the pump module 400 in the second stage is required, the computing system may compare again available power amount and required power amount for the operation of the pump module 400 in the second stage (S960), and may drive the pump module 400 by maintaining the operation stage of the pump module 400 as the second stage (S970).

The computing system may check whether the pump module 400 operates abnormally or the temperature of the CPU at preset intervals, and may stop the operation of the pump module 400 when the pump module 400 operates abnormally or the temperature of the CPU is low (S980).

In this way, the computing system may perform a cooling function by adjusting the operation stage of the pump module 400 on the basis of the temperature of the processor 100 and available power amount for the pump module 400. In addition, in a case where available power is insufficient compared to an operation stage required for the pump module 400 and thus the pump module 400 operates at a lower operation stage, a temperature control algorithm by the processor 100 may operate to perform a throttling operation. For example, the pump assembly 400 is driven using first power amount when the temperature of the processor 100 is in a first temperature range, and the pump assembly 400 is driven using second power amount greater than the first power amount when the temperature of the processor 100 is in a second temperature range higher than the first temperature range. When power amount available for the pump assembly 400 is smaller than the second power amount, the pump assembly 400 is driven using the first power amount, and the processor 100 performs a throttling operation.

When available power for the pump module 400 is insufficient, the computing system may adjust the operation stage of the pump module 400 by using the charging unit of the pump module 400. For example, the temperature of the processor 100 may change from the first temperature range to the second temperature range while the pump assembly 400 is driven using the first power amount. When energy is accumulated in the energy storage, the pump assembly 400 may be driven using the second power amount. In such a case, a sum of power amount allocated to the pump assembly 400 and power amount provided from the energy storage, which corresponds to the available power for the pump assembly 400, may be equal to or greater than the second power amount required for the pump assembly 400 when the temperature of the processor 100 is in the second temperature range. In contrast, when the energy is not accumulated in the energy storage, the pump assembly 400 is driven using the first power amount and the processor 100 performs a throttling operation.

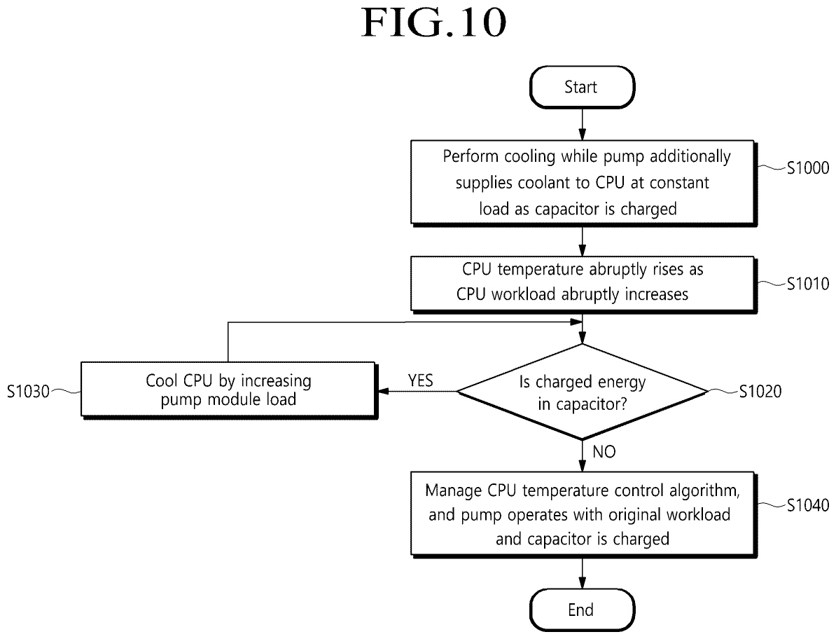

For example, referring to FIG. 10, when the pump module 400 operates, as power is charged in the capacitor which is the charging unit of the pump module 400, the pump module 400 may supply the coolant to the CPU at a constant load (S1000). For example, the pump module 400 may operate in the first stage and charge remaining power to the charging unit.

As the workload of the CPU of the computing system increases, the temperature of the CPU may rise (S1010).

The computing system may check whether power amount for the operation stage of the pump module 400 according to the risen temperature is sufficient. When power amount is not sufficient, the computing system may check power amount charged to the charging unit of the pump module 400 (S1020).

When there is power charged in the charging unit of the pump module (or pump assembly) 400, the computing system may provide a cooling function while driving the pump module 400 by increasing the operation stage of the pump module 400 (S1030). Specifically, when power amount required for driving the pump assembly 400 is greater than the power amount allocated to the pump assembly 400 and the energy is accumulated in the energy storage, the pump assembly 400 may be driven using the power amount allocated to the pump assembly 400 and the energy accumulated in the energy storage. In contrast, when power amount required for driving the pump assembly 400 is greater than the power amount allocated to the pump assembly 400 and no energy is accumulated in the energy storage, the processor (e.g., the CPU) may perform a throttling operation.

When power charged in the charging unit of the pump module 400 is not sufficient to adjust the operation stage of the pump module 400 (e.g., no power charged in the charging unit), the computing system may drive the pump module 400 according to the existing operation stage. The computing system may perform temperature control of the CPU using a temperature control algorithm, such as a throttling operation of the CPU (S1040).

Charging of power to the pump module 400 may be performed by storing the surplus of power allocated to the pump module 400 in power supplied to the slot 210. Alternatively, charging may be performed by storing the surplus of power allocated to the memory 320 and so on in power supplied to the slot 210. Alternatively, as the case may be, charging may be performed using a portion of power supplied to another slot adjacent to the slot 210.

Since the pump module 400 is driven by using a portion of power allocated to the slot 210 and, as the case may be, a charging function is used, the computing system may effectively provide a cooling function for the processor 100 while driving the pump module 400 in various stages depending on a change in the temperature of the processor 100.

The pump module 400 may be connected to a slot 210 in which power other than power allocated to the memory device 300 mounted in the slot 210 is the largest among the plurality of slots 210 included in the computing system. For example, as the pump module 400 is mounted on a memory device 300 which is connected to a slot 210 where there is a relatively large difference between power allocated to the slot 210 and power to be used by the memory device 300 mounted on the slot 210, efficiency of operating the pump module 400 may be increased.

Although some embodiments of the present disclosure have been described with particular specifics and varying details for illustrative purposes, those skilled in the art will appreciate that various modifications, additions and substitutions may be made based on what is disclosed or illustrated in the present disclosure.

What is claimed is:

1. A computing system comprising:
a processor;
a slot board on which the processor is disposed, the slot board including a plurality of slots; and
a memory device connected to a corresponding one of the plurality of slots, the memory device comprising:
a board;
at least one memory on the board; and
a pump assembly being disposed on the board, sucking at least a portion of a fluid flowing in a first direction over the processor, and discharging the sucked fluid in a second direction that intersects the first direction.

2. The computing system according to claim 1, wherein the pump assembly sucks the fluid flowing in the first direction parallel to an upper surface of the processor and discharges the sucked fluid in the second direction perpendicular or oblique to the upper surface of the processor.

3. The computing system according to claim 1, further comprising:
a heat dissipation member located on the upper surface of the processor and including at least one groove,
wherein the pump assembly discharges the sucked fluid toward the at least one groove.

4. The computing system according to claim 1, wherein the pump assembly is driven using a first portion of power allocated to the slot to which the memory device is connected, the power including the first portion and a second portion used by the at least one memory.

5. The computing system according to claim 4, wherein the pump assembly is driven using the first portion having power amount equal to or larger than that allocated to the pump assembly during at least a portion of a period in which the at least one memory is driven using the second portion having power amount smaller than that allocated to the at least one memory.

6. The computing system according to claim 4, wherein the pump assembly includes an energy storage which accumulates energy during at least a portion of a period in which the pump assembly is driven using power amount smaller than that allocated to the pump assembly.

7. The computing system according to claim 6, wherein when power amount required for driving the pump assembly is greater than the power amount allocated to the pump module and the energy is accumulated in the energy storage, the pump assembly is driven using the power amount allocated to the pump assembly and the energy accumulated in the energy storage, the power amount required for driving the pump assembly depending on a temperature of the processor.

8. The computing system according to claim 6, wherein when power amount required for driving the pump assembly is greater than the power amount allocated to the pump assembly and no energy is accumulated in the energy storage, the processor performs a throttling operation, the power amount required for driving the pump assembly depending on a temperature of the processor.

9. The computing system according to claim 1, wherein when a temperature of the processor is in a first temperature range, the pump assembly is driven using first power amount, and when the temperature of the processor is in a second temperature range higher than the first temperature range, the pump assembly is driven using second power amount larger than the first power amount.

10. The computing system according to claim 9, wherein when power amount available for the pump assembly is smaller than the second power amount, the pump assembly is driven using the first power amount, and the processor performs a throttling operation.

11. The computing system according to claim 9, wherein the temperature of the processor changes from the first temperature range to the second temperature range while the pump assembly is driven using the first power amount,
wherein when the energy is accumulated in the energy storage, the pump assembly is driven using the second power amount, and
wherein when the energy is not accumulated in the energy storage, the pump assembly is driven using the first power amount and the processor performs a throttling operation.

12. The computing system according to claim 1, wherein the at least one memory includes at least one first memory which is disposed on a first surface of the board and at least one second memory which is disposed on a second surface of the board, the pump assembly is disposed on the first surface, and the number of the at least one first memory is different from that of the at least one second memory.

13. A computing system comprising:
a processor; and
a first memory device connected to a first slot, the first memory device comprising:
a first board;
at least one first memory on the first board; and
a pump assembly being disposed on the first board, sucking a fluid flowing over the processor in a first direction, and discharging the sucked fluid in a second direction that intersects the first direction.

14. The computing system according to claim 13, further comprising:
a second memory device connected to a second slot,
wherein the second memory device comprises:
a second board; and
at least one second memory on the second board.

15. The computing system according to claim 14, wherein the first slot is located closer to the processor than the second slot.

16. The computing system according to claim 14, wherein the number of the at least one second memory is greater than that of the at least one first memory.

17. The computing system according to claim 14, wherein an amount of first power allocated to the first slot is substantially the same as that of second power allocated to the second slot.

18. A memory device comprising:
a board;
at least one memory on the board; and
a pump assembly disposed on the board, sucking at least a portion of a fluid flowing in a first direction, and discharging the sucked fluid in a second direction that intersects the first direction.

19. The memory device according to claim 18, wherein the first direction is a direction parallel to a surface of the board, the at least one memory being disposed on the surface of the board.

20. The memory device according to claim 18, wherein the second direction is a direction that is perpendicular or oblique to the first direction.
